(19) United States
(12) Patent Application Publication
(10) Pub. No.: US 2025/0301760 A1
(43) Pub. Date: Sep. 25, 2025

(54) POWER SEMICONDUCTOR DEVICE AND POWER CONVERSION DEVICE

(71) Applicant: Mitsubishi Electric Corporation, Chiyoda-ku, Tokyo (JP)

(72) Inventors: Haruna TADA, Tokyo (JP); Yasuyuki SANDA, Tokyo (JP); Masaki GOTO, Tokyo (JP); Tatsushi MORISADA, Tokyo (JP); Hayato TERADA, Tokyo (JP); Hodaka ROKUBUICHI, Tokyo (JP); Yoshinori ITO, Tokyo (JP)

(73) Assignee: Mitsubishi Electric Corporation, Chiyoda-ku, Tokyo (JP)

(21) Appl. No.: 18/863,681

(22) PCT Filed: Jul. 7, 2023
(86) PCT No.: PCT/JP2023/025284

§ 371 Date: Nov. 7, 2024

(30) Foreign Application Priority Data
Jul. 14, 2022 (JP) 2022-113036

(51) Int. Cl. H10D 80/20; H01L 23/31; H01L 23/367; H01L 23/373; H01L 25/07; H02P 27/08

(52) U.S. Cl. CPC H10D 80/20; H01L 23/3107; H01L 23/3672; H01L 23/3735; H01L 25/072; H02P 27/08

(57) ABSTRACT

A first surface shape of a module base and a second surface shape of a heatsink base are fitted to each other, and thus the module base and the heatsink base are fixed to each other. One of the first surface shape and the second surface shape includes a first protrusion and a second protrusion, and the other includes a first recess fitted to the first protrusion and a second recess fitted to the second protrusion. The first protrusion has a tip end in contact with the first recess, and the second protrusion has a tip end away from the second recess.

### TECHNICAL FIELD

The present disclosure relates to a power semiconductor device and a power conversion apparatus, and particularly relates to a power semiconductor device including a heatsink base and a power conversion apparatus including the power semiconductor device.

### BACKGROUND ART

PCT International Publication No. 2018/079396 (Patent Document 1) discloses a semiconductor device. The semiconductor device includes a power module and a heat dissipation member. The power module includes a semiconductor element, a metal component mounted with the semiconductor element, and a sealing material sealing the semiconductor element and exposing at least a part of the metal component. Any one of a plurality of recesses or protrusions is formed in the metal component, and the other one of the plurality of recesses or protrusions is formed in the heat dissipation member. The metal component and the heat dissipation member are integrated at a plurality of protruding-recessed portions where the plurality of recesses and the plurality of protrusions are in contact with each other. A first protruding-recessed portion, which is a part of the plurality of protruding-recessed portions, is larger in dimension in the height direction than a second protruding-recessed portion other than the first protruding-recessed portion among the plurality of protruding-recessed portions.

In a method for manufacturing the semiconductor device, swaging is performed on the recess and the protrusion in order to integrate the metal component and the heat dissipation member. At this time, the first recess and the first protrusion constituting the first protruding-recessed portion larger in dimension in the height direction than the second protruding-recessed portion have a role of preventing the power module from deviating and being integrated with the heatsink so as to be inclined with respect to the original joining mode, in other words, a role of a guide mechanism.

### PRIOR ART DOCUMENT

### Patent Document

Patent Document 1: PCT International Publication No. 2018/079396

### SUMMARY

### Problem to Be Solved by the Invention

When a relative position between the members to be integrated by the swaging is deviated from an ideal position in design due to at least any of an inclination between the members and a superposition deviation between the members, a load necessary for completing the swaging, that is, a necessary load may increase. According to the semiconductor device, the position deviation can be suppressed by the guide mechanism but cannot always be sufficiently suppressed. Therefore, even if the guide mechanism is provided, there may be a concern about an increase in the necessary load due to the position deviation. Depending on the design of the semiconductor device, the guide mechanism is sometimes not permitted to be provided. The guide mechanism is unnecessary if a precise alignment process is performed before swaging, but introducing such a process imposes a heavy burden on manufacturing. Not only the position deviation but also a dimensional error of the member leads to an increase in the necessary load.

As described above, the necessary load for the swaging may increase due to manufacturing variation that causes at least any of the position deviation and the dimensional error. On the other hand, simply adjusting the design of the protruding-recessed portion so as to reduce the necessary load tends to lead to a decrease in the strength of the swaging joint and an increase in the thermal contact resistance in the swaging joint.

The present disclosure has been made to solve the above problems, and an object of the present disclosure is to provide a power semiconductor device that can suppress a decrease in strength of swaging joint and an increase in thermal contact resistance in the swaging joint while suppressing an increase in the necessary load for swaging due to manufacturing variations.

### Means to Solve the Problem

A power semiconductor device according to the present disclosure includes a module base, a semiconductor element, a resin sealing portion, and a heatsink base. The module base has a mounting surface and a back surface opposite to the mounting surface in a thickness direction. The semiconductor element is mounted on the mounting surface of the module base. The resin sealing portion seals the semiconductor element on the mounting surface of the module base. The heatsink base has an attachment surface attached to the back surface of the module base, and a heat dissipation surface opposite to the attachment surface in the thickness direction. A first surface shape of the back surface of the module base and a second surface shape of the attachment surface of the heatsink base are fitted to each other, and thus the back surface of the module base and the attachment surface of the heatsink base are fixed to each other. One of the first surface shape and the second surface shape includes a first protrusion and a second protrusion, and the other includes a first recess fitted to the first protrusion and a second recess fitted to the second protrusion. The first protrusion has a tip end in contact with the first recess, and the second protrusion has a tip end away from the second recess.

### EFFECTS OF THE INVENTION

According to the present disclosure, it is possible to suppress a decrease in strength of swaging joint and an increase in thermal contact resistance in the swaging joint while suppressing an increase in the necessary load for swaging due to manufacturing variations.

### BRIEF DESCRIPTION OF DRAWINGS

FIG. 1 is a cross sectional view schematically showing a configuration of a power semiconductor device in a first embodiment.

FIG. 2 is a cross sectional view schematically showing a state before swaging joint of a module base and a heatsink base of the power semiconductor device shown in FIG. 1.

FIG. 3 is a partial plan view schematically showing a configuration of a back surface of the module base shown in FIG. 2.

FIG. 4 is a partial plan view showing a modification of the back surface of the module base shown in FIG. 3.

FIG. 5 is a partial plan view showing a modification of the back surface of the module base shown in FIG. 3.

FIG. 6 is a partial cross sectional view schematically showing a configuration of a second protrusion and a second recess shown in FIG. 1.

FIG. 7 is a partial cross sectional view schematically showing a state immediately before a swaging process in a method for manufacturing a power semiconductor device of a comparative example.

FIG. 8 is a partial cross sectional view schematically showing a state immediately after the swaging process in the method for manufacturing the power semiconductor device of the comparative example.

FIG. 9 is a partial cross sectional view schematically showing a state immediately before a swaging process in a method for manufacturing the power semiconductor device in the first embodiment.

FIG. 10 is a partial cross sectional view schematically showing a state immediately after the swaging process in the method for manufacturing the power semiconductor device in the first embodiment.

FIG. 11 is a cross sectional view showing a modification of the heatsink shown in FIG. 2.

FIG. 12 is a cross sectional view showing a modification of the heatsink shown in FIG. 2.

FIG. 13 is a cross sectional view schematically showing a state before swaging joint of a module base and a heatsink base of the modification of the power semiconductor device shown in FIG. 2.

FIG. 14 is a partial cross sectional view showing dimensions of the module base and the heatsink base shown in FIG. 13.

FIG. 15 is a cross sectional view schematically showing a state before swaging joint of the module base and the heatsink base of the modification of the power semiconductor device shown in FIG. 2.

FIG. 16 is a cross sectional view schematically showing a state before swaging joint of the module base and the heatsink base of the modification of the power semiconductor device shown in FIG. 2.

FIG. 17 is a cross sectional view schematically showing a state before swaging joint of the module base and the heatsink base of the modification of the power semiconductor device shown in FIG. 2.

FIG. 18 is a cross sectional view schematically showing a state immediately before the swaging process in the method for manufacturing the power semiconductor device in the first embodiment.

FIG. 19 is a cross sectional view schematically showing a state during the swaging process in the method for manufacturing the power semiconductor device in the first embodiment.

FIG. 20 is a cross sectional view schematically showing a state immediately after the swaging process in the method for manufacturing the power semiconductor device in the first embodiment.

FIG. 21 is a plan view for explaining a modification of the swaging process in the method for manufacturing the power semiconductor device in the first embodiment.

FIG. 22 is a cross sectional view schematically showing a modification of the swaging process in the method for manufacturing the power semiconductor device in the first embodiment.

FIG. 23 is a cross sectional view schematically showing a configuration of a power semiconductor device in a second embodiment.

FIG. 24 is a cross sectional view schematically showing a state before swaging joint of a module base and a heatsink base of the power semiconductor device shown in FIG. 23.

FIG. 25 is a cross sectional view schematically showing a configuration of a power semiconductor device in a third embodiment.

FIG. 26 is a cross sectional view schematically showing one process in a method for manufacturing the power semiconductor device in the third embodiment.

FIG. 27 is a cross sectional view schematically showing one process in the method for manufacturing the power semiconductor device in the third embodiment.

FIG. 28 is a block diagram schematically showing a configuration of a power conversion apparatus in a fourth embodiment.

### DESCRIPTION OF EMBODIMENTS

Hereinafter, embodiments will be described with reference to the drawings. Note that in the following drawings, the same or corresponding parts are denoted by the same reference numerals, and the description thereof will not be repeated. In the present description, the term “metal” can mean not only a pure metal but also an alloy unless otherwise specified.

### First Embodiment

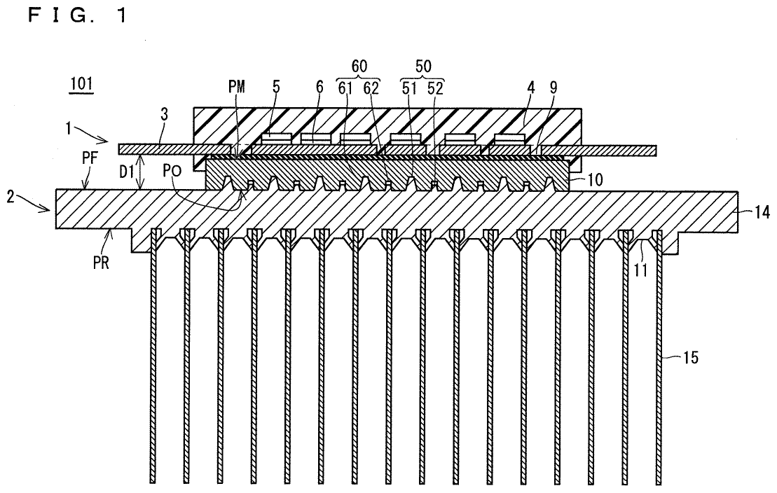

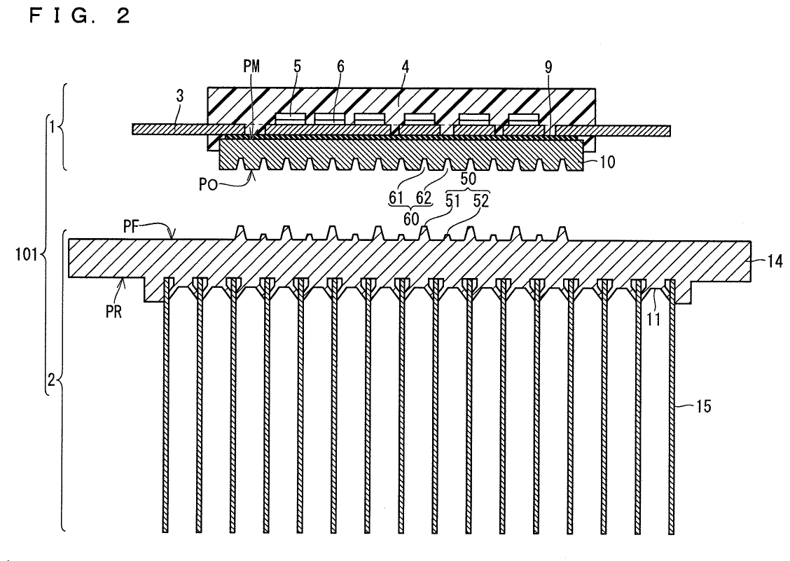

FIG. 1 is a cross sectional view schematically showing the configuration of a power semiconductor device 101 in the first embodiment. The power semiconductor device 101 includes a power module unit 1 and a heatsink unit 2. The power semiconductor device 101 is a device in which the power module unit 1 and the heatsink unit 2 are integrated, in other words, a heatsink integrated power module. FIG. 2 is a cross sectional view schematically showing a state before a module base 10 of the power module unit 1 and a heatsink base 14 of the heatsink unit 2 are joined by swaging. Note that swaging between the module base and the heatsink base may be called “heatsink swaging” below. Note that the timing of heatsink swaging in manufacturing of the power semiconductor device 101 is not limited to one, and the same applies to other embodiments. FIG. 2 described above corresponds to a case where the heatsink swaging is performed alone in the last process in manufacturing.

The power module unit 1 includes a module base 10, at least one semiconductor element 5 (semiconductor chip), and a resin sealing portion 4 (mold). The power module unit 1 may include a lead frame 3.

The module base 10 has a mounting surface PM and a back surface PO opposite to the mounting surface PM in the thickness direction (longitudinal directions in FIGS. 1 and 2). The semiconductor element 5 is mounted on the mounting surface PM of the module base 10. For this mounting, for example, a joint material 6 made of solder may be used. The semiconductor element 5 includes a power semiconductor element. The power semiconductor element is, for example, a switching element or a freewheeling diode. The semiconductor element 5 may be a semiconductor element using a wide band gap semiconductor, that is, a wide band gap semiconductor element. The wide band gap semiconductor is, for example, silicon carbide (SiC). The resin sealing portion 4 seals the semiconductor element 5 on the mounting surface PM of the module base 10. The lead frame 3 (metal electrode) may be attached on the mounting surface PM of the module base 10, and an insulating sheet 9 may be provided between the lead frame 3 and the mounting surface PM. The lead frame 3 is electrically connected to the semiconductor element 5. Note that for this electrical connection, a wiring member (typically, a bonding wire) not shown may be used. The lead frame 3 includes a part covered with the resin sealing portion 4 and a part projecting outward from the resin sealing portion 4.

The heatsink unit 2 includes the heatsink base 14. The heatsink base 14 has an attachment surface PF attached to the back surface PO of the module base 10 and a heat dissipation surface PR opposite to the attachment surface PF in the thickness direction. In the present embodiment, the heatsink unit 2 includes a heat dissipation fin 15 attached to the heat dissipation surface PR of the module base 10. The heat dissipation fin 15 is attached to a swage portion 11 of the module base 10 by swaging joint. Hereinafter, this swaging may be called “fin swaging”.

The module base 10 of the power module unit 1 and the heatsink base 14 of the heatsink unit 2 are separately prepared and then joined to each other by heatsink swaging. Therefore, the design of the heatsink unit 2 can be changed without changing the design of the module base 10, and the heat dissipation capability for removing heat from the semiconductor element 5 can be adjusted by the change. Design elements of the heatsink unit 2 for adjusting heat dissipation capability include, for example, the dimension of the heatsink base 14 in an in-plane direction perpendicular to the thickness direction, the number of heat dissipation fins 15, and the size of each of the heat dissipation fins 15. Since the design of the module base 10 that is common can be applied by changing the design of the heatsink unit 2 in accordance with the required heat dissipation capability, productivity of the power module unit 1 can be enhanced. Since it is not necessary to change the design of the mold for preparing the module base 10, an increase in mold cost can be avoided.

The module base 10 is made of metal. For example, the module base 10 is made of aluminum or an aluminum alloy, and is prepared by cutting, die casting, forging, or extrusion. The heatsink base 14 is made of metal. For example, the heatsink base 14 is made of aluminum or an aluminum alloy, and is prepared by cutting, die casting, forging, or extrusion. The heat dissipation fin 15 is made of, for example, a metal plate (rolled material) such as aluminum or an aluminum alloy.

The surface shape (hereinafter, also called “first surface shape”) of the back surface PO of the module base 10 and the surface shape (hereinafter, also called “second surface shape”) of the attachment surface PF of the heatsink base 14 are fitted to each other as shown in FIG. 1, and thus the back surface PO of the module base 10 and the attachment surface PF of the heatsink base 14 are fixed to each other. One of the first surface shape and the second surface shape includes a first protrusion 51 and a second protrusion 52, and the other includes a first recess 61 fitted to the first protrusion 51 and a second recess 62 fitted to the second protrusion 52. In the examples shown in FIGS. 1 and 2, the second surface shape includes the first protrusion 51 and the second protrusion 52, and the first surface shape includes the first recess 61 and the second recess 62.

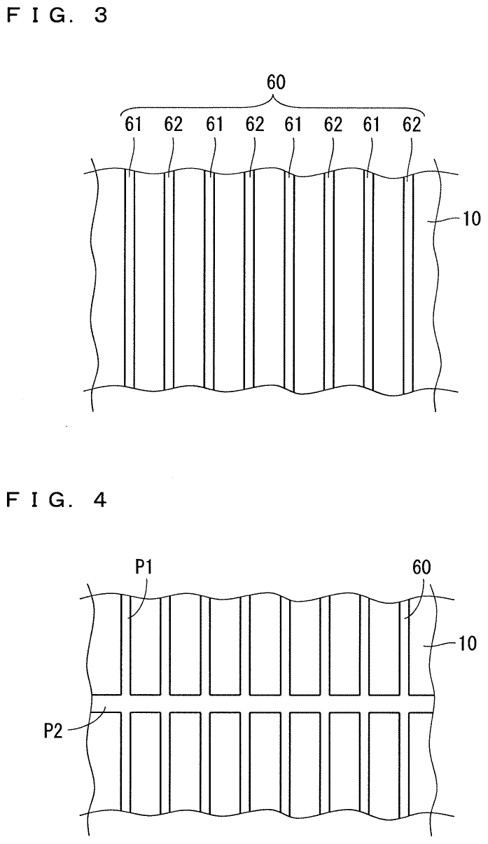

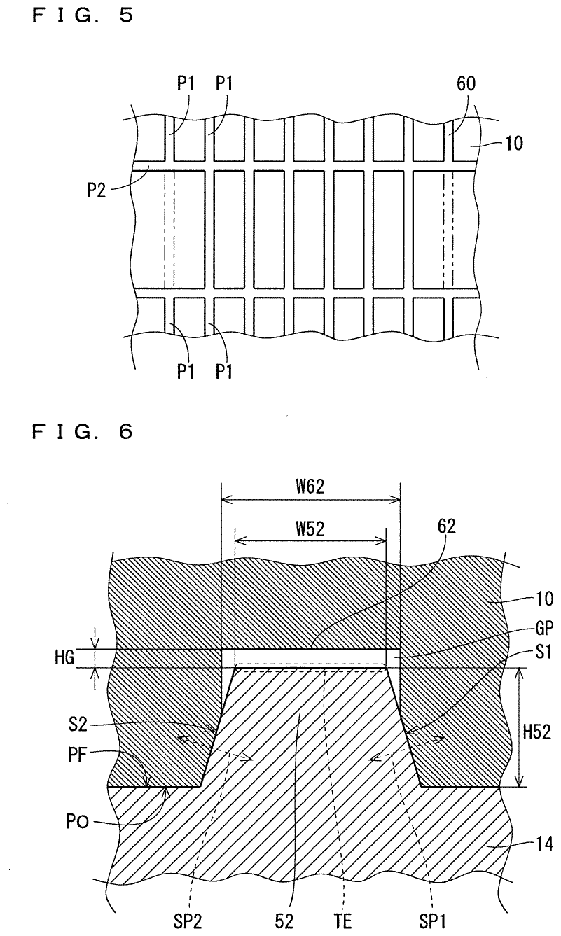

FIG. 3 is a partial plan view schematically showing the configuration of the back surface PO (FIG. 2) of the module base 10. The planar layout perpendicular to the thickness direction of a recess group 60 including the first recess 61 and the second recess 62 includes a plurality of patterns each extending along the first direction (longitudinal direction in FIG. 3) and arranged at intervals in the second direction (lateral direction in FIG. 3) perpendicular to the first direction. Note that a protrusion group including the first protrusion 51 and the second protrusion 52 may also have a planar layout corresponding to the planar layout. Each of FIGS. 4 and 5 is a partial plan view showing the modification of FIG. 3. In these modifications, the planar layout perpendicular to the thickness direction of the recess group 60 includes a plurality of patterns P1 each extending along the first direction (longitudinal direction in the figures) and arranged at intervals in the second direction (lateral direction in the figures) perpendicular to the first direction, and at least one pattern P2 extending along the third direction (lateral direction in the figures) different from the first direction. In particular, the modification of FIG. 5 includes a pattern extending discontinuously along the first direction, as indicated by a two-dot chain line in the drawing.

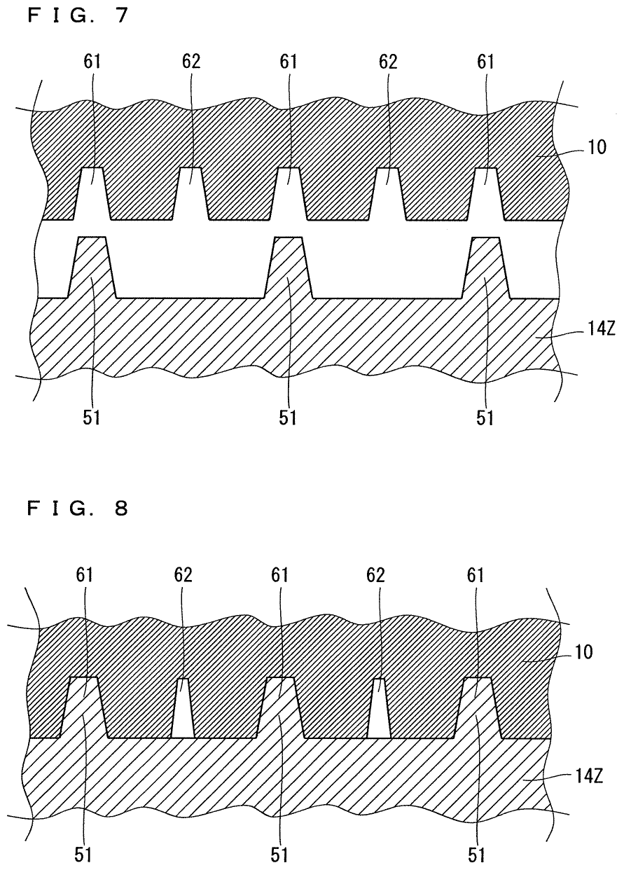

FIG. 6 is a partial cross sectional view schematically showing the configurations of the second protrusion 52 and the second recess 62 in cross sectional view parallel to the thickness direction. The second protrusion 52 has a tip end TE away from the second recess 62. Therefore, a gap GP is formed between the second protrusion 52 and the second recess 62. In the example of FIG. 6, the tip end TE of the second protrusion 52 is a surface projecting at a height H52 that is substantially uniform from a substantially flat surface (lower surface in FIG. 6) of the attachment surface PF. The tip end TE of the second protrusion 52 is away from the second recess 62, while a side surface of the second protrusion 52 is in contact with a side wall of the second recess 62. The height H52 is preferably 0.5 mm or more. The tip end TE of the second protrusion 52 has a width W52 of the second protrusion 52. The second recess 62 has a width W62 at the position of the tip end TE of the second protrusion 52 in the thickness direction. The width W52 is preferably 65% or more and less than 100% of the width W62. Here, the dimension of the width is a dimension in a direction perpendicular to the extending direction, and is a dimension in a lateral direction in any of FIGS. 3 to 5, for example. A distance HG between the tip end TE of the second protrusion 52 and a bottom surface of the second recess 62 may be greater than zero, may be 0.1 mm or more, or may be 0.2 mm or more.

The first protrusion 51 (FIG. 1) has a tip end in contact with the first recess 61. In a cross sectional view (FIG. 1) parallel to the thickness direction, a gap does not need to be formed between the first protrusion 51 and the first recess 61, but a gap may be formed between the first protrusion 51 and the first recess 61. The gap is preferably smaller than the gap GP (FIG. 6) between the second protrusion 52 and the second recess 62, and preferably has an area of 50% or less of the area of the first recess 61. The height H52 (FIG. 6) of the second protrusion 52 is preferably smaller than the height of the first protrusion 51.

Surface pressure is applied at least locally between the first protrusion 51 and the first recess 61 for the purpose of swaging joint. The surface pressure is not necessarily applied between the second protrusion 52 and the second recess 62, but the surface pressure may be applied at least locally. When the surface pressure is applied, the maximum surface pressure between the second protrusion 52 and the second recess 62 is preferably lower than the maximum surface pressure between the first protrusion 51 and the first recess 61. In the cross sectional view shown in FIG. 6, a right side surface and a left side surface of the first protrusion 51 are applied with surface pressure SP1 and surface pressure SP2, respectively. As a modification, the surface pressure SP1 or the surface pressure SP2 may be zero, and as another modification, the surface pressure SP1 and the surface pressure SP2 may be zero.

Note that a fluid (typically, air) may flow through the gap GP (FIG. 6) during an operation of the power semiconductor device 101. This promotes heat dissipation from the heatsink unit 2. This effect is particularly remarkable when forced air cooling using a fan or the like is applied.

The process state may be inspected by observing the gap GP during heatsink swaging or after heatsink swaging. For example, the area of the gap GP in an in-plane direction perpendicular to the extending direction of the second recess 62 may be observed. Such observation may be performed by measuring a projection area of light passing through the gap GP, for example. The state of the heatsink swaging can be automatically inspected by an automatic inspection apparatus including a mechanism for performing such measurement.

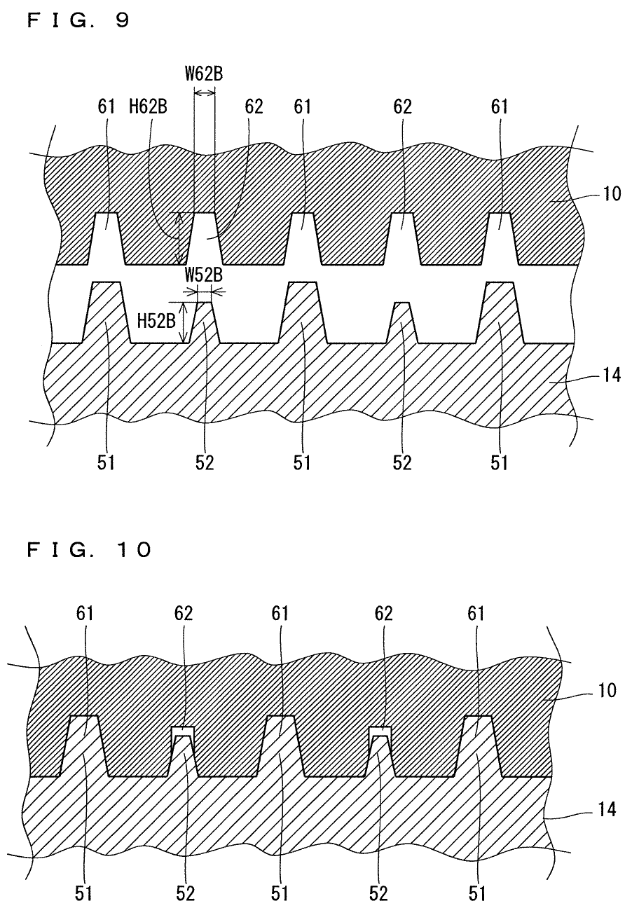

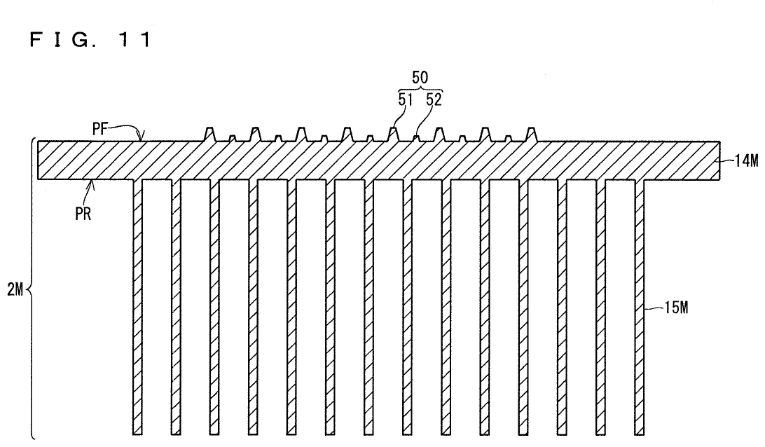

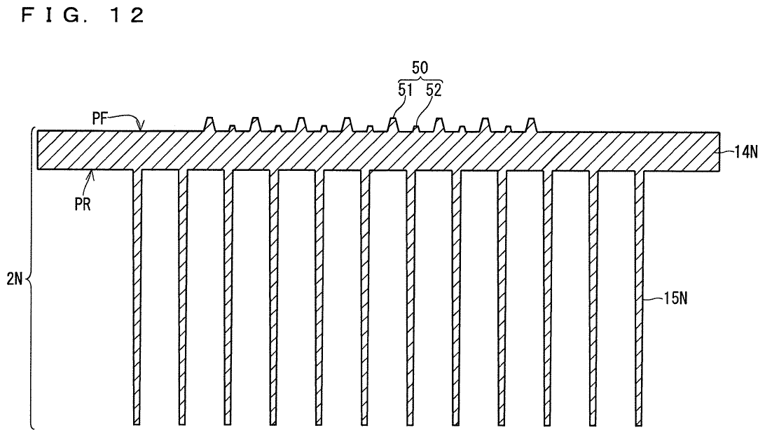

FIGS. 7 and 8 are partial cross sectional views schematically showing states immediately before and immediately after a swaging process, respectively, in the method for manufacturing the power semiconductor device of the comparative example. FIGS. 9 and 10 are partial cross sectional views schematically showing states immediately before and immediately after a swaging process, respectively, in the method for manufacturing the power semiconductor device 101 in the first embodiment. A press load for swaging is substantially equal between the comparative example (FIGS. 7 and 8) and the first embodiment. Unlike the heatsink base 14 (FIGS. 9 and 10) of the present embodiment, a heatsink base 14Z of the comparative example (FIGS. 7 and 8) includes the second recess 62 but does not include the second protrusion 52 (FIGS. 9 and 10: the present embodiment).

In the swaging process of the comparative example (FIGS. 7 and 8), if swaging is started in a state where a position deviation between the heatsink base 14Z and the module base 10 is too large to be ignored, it is necessary to plastically deform the module base 10 so that the first recess 61 is increased more than that in a case where there is substantially no position deviation. At that time, since the inside of the second recess 62 is completely hollow, the second recess 62 can be relatively freely reduced so as to absorb the increase of the first recess 61. Therefore, even if there is a certain degree of the position deviation, there is almost no increase in the necessary load in the swaging. On the other hand, the surface pressure between the first protrusion 51 and the first recess 61 decreases due to the reduction of the second recess 62. As a result, there is a concern about occurrence of a decrease in the strength of the swaging joint and an increase in the thermal contact resistance in the swaging joint.

On the other hand, in the swaging of the first embodiment (FIGS. 9 and 10), the heatsink base 14 is provided with the second protrusion 52. Immediately before the swaging (FIG. 9), at least any of the following first and second conditions is satisfied. As the first condition, a height H52B of the second protrusion 52 is smaller than a depth H62B of the second recess 62. As the second condition, a width W52B of the tip end of the second protrusion 52 is smaller than a width W62B of the bottom of the second recess 62.

In the swaging process of the first embodiment (FIGS. 9 and 10), if swaging is started in a state where a position deviation between the heatsink base 14 and the module base 10 is too large to be ignored, it is necessary to plastically deform the module base 10 so that the first recess 61 is increased more than that in a case where there is substantially no position deviation. At that time, since the second protrusion 52 smaller than the second recess 62 is inserted into the second recess 62, as the second recess 62 is reduced so as to absorb the increase of the first recess 61, the contact between the second recess 62 and the second protrusion 52 progresses, and the surface pressure therebetween further increases. Due to the reduction of the second recess 62, the surface pressure between the first protrusion 51 and the first recess 61 decreases. This leads to a decrease in strength of the swaging joint and an increase in thermal contact resistance in the swaging joint. On the other hand, as described above, progress in the contact between the second recess 62 and the second protrusion 52 and a further increase in the surface pressure therebetween lead to a decrease in strength of the swaging joint and an increase in thermal contact resistance in the swaging joint. Therefore, it is possible to suppress a decrease in strength of swaging joint and an increase in thermal contact resistance in swaging joint, which are concerned in the comparative example.

According to the first embodiment, the first protrusion 51 includes the tip end (FIG. 1) in contact with the first recess 61, and the second protrusion 52 has the tip end TE (FIG. 6) away from the second recess 62. This can start proceeding with the swaging of the first protrusion 51 and the first recess 61 prior to the swaging of the second protrusion 52 and the second recess 62 in the swaging in manufacture of the power semiconductor device 101. At that time, the swaging of the first protrusion 51 and the first recess 61 may be difficult to proceed due to manufacturing variation that causes at least any of the position deviation and the dimensional error. In that case, when the swaging is continued to proceed, the surface pressure between the first protrusion 51 and the first recess 61 increases, and due to this, plastic deformation occurs such that the second recess 62 is reduced. This plastic deformation suppresses an increase in surface pressure between the first protrusion 51 and the first recess 61. Therefore, it is possible to avoid an excessive increase in the necessary load of the swaging. On the other hand, an excessive reduction of the second recess 62 is prevented by being obstructed by the second protrusion 52. Therefore, the surface pressure between the first protrusion 51 and the first recess 61 is prevented from becoming excessively small. Therefore, it is possible to suppress a decrease in strength of swaging joint and an increase in thermal contact resistance in swaging joint due to the fact that the surface pressure between the first protrusion 51 and the first recess 61 is excessively small. From the above, it is possible to suppress a decrease in strength of swaging joint and an increase in thermal contact resistance in swaging joint while suppressing an increase in the necessary load for swaging due to manufacturing variations.

Due to the above effect, the position deviation allowed during the heatsink swaging becomes larger. This can enhance productivity of the power semiconductor device. A simpler jig can be used as a jig for the heatsink swaging.

A large necessary load of the swaging may reduce productivity of the power semiconductor device, or reduce reliability by damaging members of the power semiconductor device. Examples of phenomena leading to the reduction in reliability include a damage to the semiconductor element 5 (semiconductor chip), a crack in the semiconductor element 5, a change in characteristics of the semiconductor element 5, a crack in the resin sealing portion 4, a reduction in withstand voltage of the power semiconductor device 101, and peeling between members of the power semiconductor device 101. By suppressing the necessary load as described above, productivity can be enhanced or reliability can be enhanced. From another point of view, since the necessary load is suppressed as described above, the position deviation of the member to be swaged is more allowable. Therefore, productivity of the power semiconductor device can be enhanced.

As a result of plastic deformation of the second recess 62, contact between the second protrusion 52 and the second recess 62 also contributes to suppression of an increase in thermal contact resistance. The surface pressures applied between the second protrusion 52 and the second recess 62 also contributes to suppression of a decrease in joint strength.

The surface of the heat dissipation fin 15 may be embossed to impart a minute recess. The heat dissipation fin 15 may be prepared by pressing using a mold, and if embossing is performed at the time of the pressing, an increase in cost for embossing can be almost avoided. An increase in the heat dissipation area by embossing improves heat dissipation performance. In a case where the heat dissipation fins 15 as members used for manufacturing the power semiconductor device 101 are stacked, if the heat dissipation fins 15 are embossed, the contact area between the heat dissipation fins 15 is reduced, and thus the surface friction between the heat dissipation fins 15 is reduced. Reduction in the surface friction can simplify the production facility of the fin swaging and shorten the production tact, thus improving productivity. If the heat dissipation fin 15 is embossed, at the time of fin swaging, the swage portion 11 of the heatsink base 14 intrudes deeper into an embossed part of the surface of the heat dissipation fin 15 as compared with a part not embossed, this exerts an anchor effect, and thus, friction in the thickness direction (longitudinal directions in FIGS. 1 and 2) between the heat dissipation fin 15 and the swage portion 11 of the heatsink base 14 increases. This improves the vertical tensile strength of the heat dissipation fin 15 after fin swaging.

In particular, when the heat dissipation fin 15 is harder than the heatsink base 14, in fin swaging, the swage portion 11 of the heatsink base 14 only plastically deforms along the surface of the heat dissipation fin 15, and hardly bites into the inside of the surface. Therefore, embossing in advance particularly improves the vertical tensile strength of the heat dissipation fin after fin swaging. On the other hand, when the heatsink base 14 is harder than the heat dissipation fin 15, the swage portion 11 of the heatsink base 14 easily bites into the inside of the surface of the heat dissipation fin 15 in fin swaging, thereby exerting the anchor effect. Therefore, when the heatsink base 14 is harder than the heat dissipation fin 15, the effect of embossing on the heat dissipation fin 15 is small. Therefore, from the point of view of the vertical tensile strength of the heat dissipation fin 15 after fin swaging, at least any of embossing on the surface of the heat dissipation fin 15 and selecting a material harder than the material of the heat dissipation fin 15 as a material of the heatsink base 14 is preferably performed. For example, when the material of the heatsink base 14 is an aluminum 6000 material and the material of the heat dissipation fin 15 is an aluminum 1000 material, the vertical tensile strength of the heat dissipation fin 15 is about 2.5 to 3.6 times as large as that in a case where the material of the heatsink base 14 and the material of the heat dissipation fin 15 are both aluminum 1000 materials.

However, the material of the heatsink base 14 and the material of the heat dissipation fin 15 are not limited to the aluminum material, and may be different materials from each other. For example, from the point of view of heat dissipation capability, the heat dissipation capability is improved by preparing the heat dissipation fin 15 from a copper plate material having a thermal conductivity higher than that of the aluminum material. The heatsink unit 2 is prepared by swaging and joining the heatsink base 14 and the heat dissipation fin 15 separately prepared, and process restriction (aspect ratio) of die casting or extrusion when each of the heatsink base 14 and the heat dissipation fin 15 is prepared is not a problem, and thus the heat dissipation fin can be relatively freely designed to improve heat dissipation capability of the heatsink unit 2.

FIG. 11 is a cross sectional view showing a heatsink unit 2M of a modification of the heatsink unit 2 (FIG. 2). In creation of the heatsink unit 2M, a heatsink base 14M and a heat dissipation fin 15M are integrally formed from the beginning, and thus fin swaging is unnecessary. The heatsink unit 2M is prepared by, for example, extrusion, cutting, or forging. FIG. 12 is a cross sectional view showing a heatsink unit 2N of a modification of the heatsink unit 2 (FIG. 2). In creation of the heatsink unit 2N, a heatsink base 14N and the heat dissipation fin 15N are integrally formed from the beginning, and thus fin swaging is unnecessary. The heatsink unit 2N is prepared by, for example, die casting.

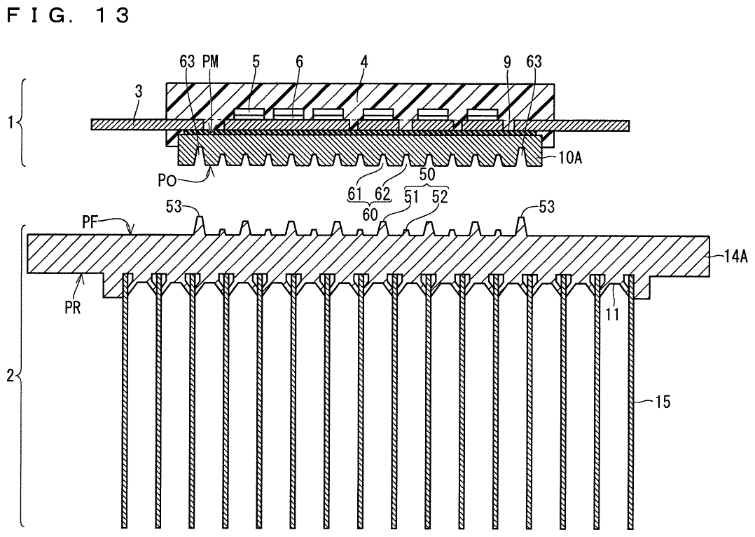

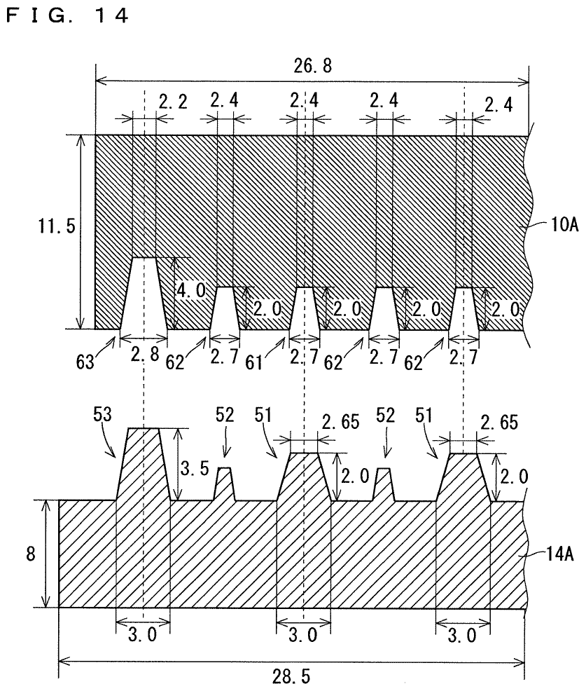

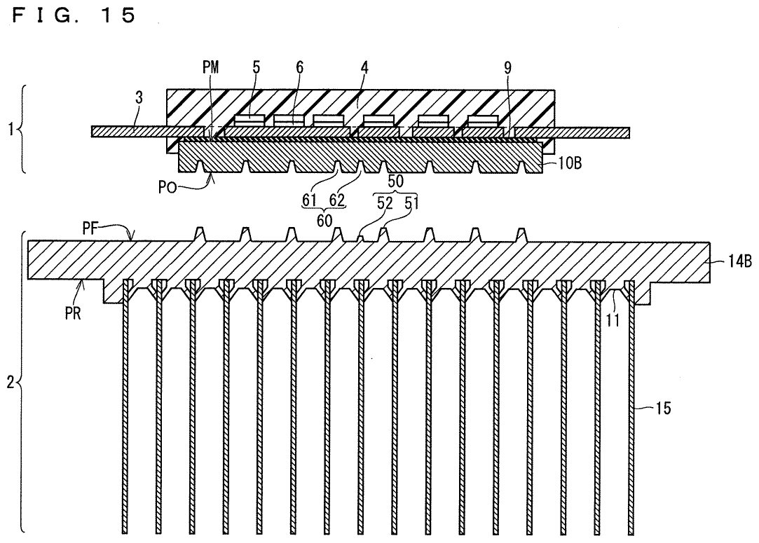

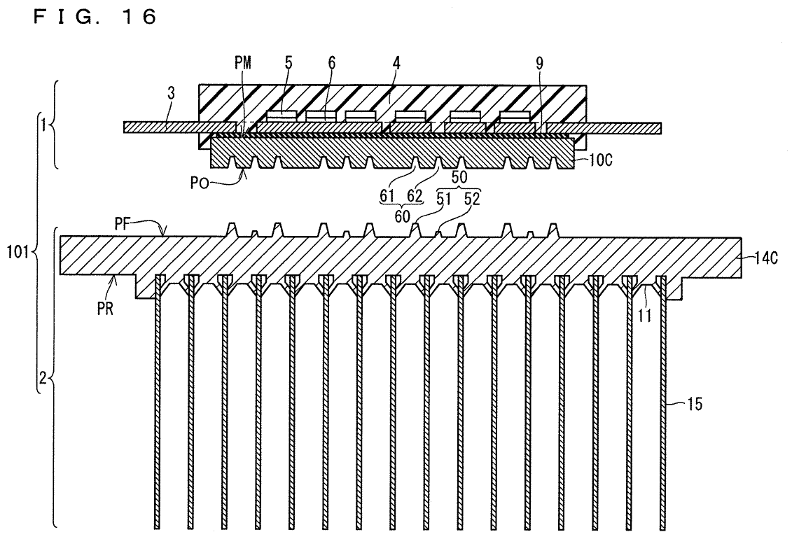

FIG. 13 is a cross sectional view schematically showing a state before swaging joint of a module base 10A and a heatsink base 14A of a modification of the power semiconductor device 101 (FIG. 2). A surface shape (first surface shape) of the back surface PO of the module base 10A is provided with a guide recess 63. The depth of the guide recess 63 is larger than the depth of the first recess 61 and the depth of the second recess 62. A surface shape (second surface shape) of the attachment surface PF of the heatsink base 14A is provided with a guide protrusion 53. The depth of the guide protrusion 53 is larger than the depth of the first protrusion 51 and the depth of the second protrusion 52. In the example shown in FIG. 13, the guide recesses 63 are provided at two locations (left side and right side in the figure) on the back surface PO of the module base 10A, and the guide protrusions 53 are provided at two locations (left side and right side in the figure) on the attachment surface PF of the heatsink base 14A. FIG. 14 is a partial cross sectional view showing dimensions of the module base 10A and the heatsink base 14A shown in FIG. 13.

When the heatsink swaging is started, the module base 10A and the heatsink base 14A can be roughly positioned first by using the guide protrusion 53 and the guide recess 63. As the swaging proceeds, the guide protrusion 53 slides in the guide recess 63, whereby the position deviation can be corrected to some extent. Due to this effect, the position deviation allowed during the heatsink swaging becomes larger. This can enhance productivity of the power semiconductor device. A simpler jig can be used as a jig for the heatsink swaging.

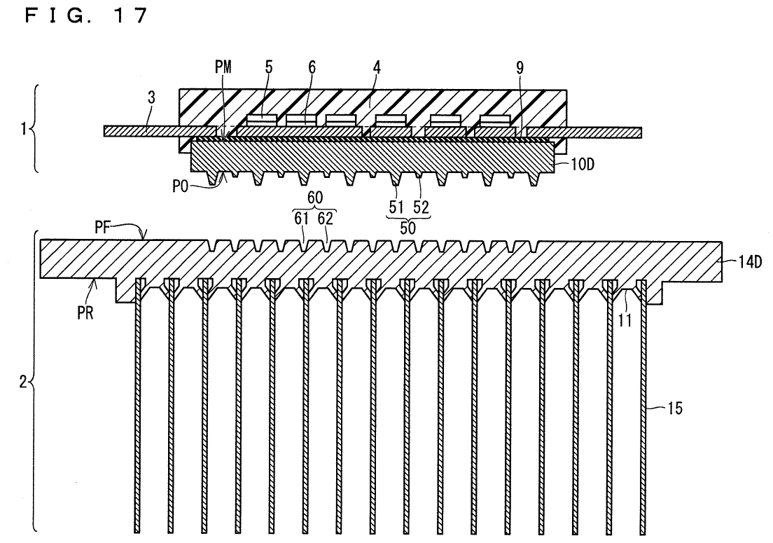

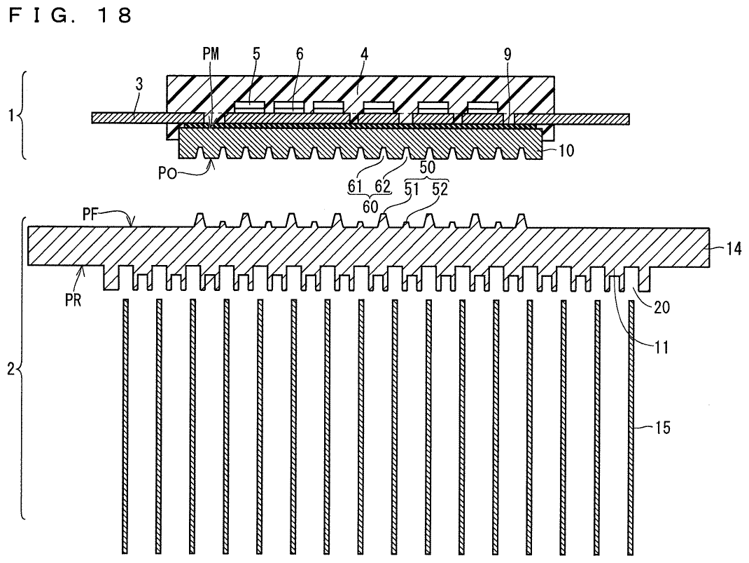

In the heatsink swaging, as described above, when the surface pressure between the second recess 62 and the second protrusion 52 increases as the second recess 62 decreases, the necessary load of the swaging increases to some extent. The degree of this increase can be appropriately controlled by adjusting the numbers and dimensions of the second protrusion 52 and the second recess 62. Each of FIGS. 15 and 16 shows a modification from this point of view. In FIG. 15, a module base 10B includes only one second recess 62, and a heatsink base 14B includes only one second protrusion 52. In FIG. 16, a module base 10C includes the second recesses 62 at every other position between the first recesses 61, and the heatsink base 14B includes the second protrusions 52 at every other position between the first protrusions 51.

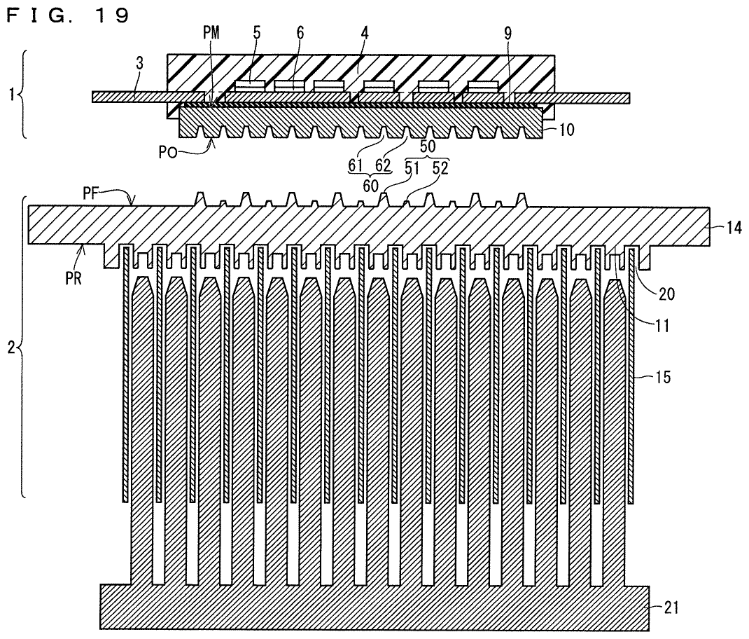

FIG. 17 is a cross sectional view schematically showing a state before swaging joint of the module base 10 and the heatsink base 14 of a modification of the power semiconductor device 101 (FIG. 2). Contrary to the power semiconductor device 101 (FIG. 2), in the present modification, the surface shape (first surface shape) of the back surface PO of a module base 10D includes the first protrusion 51 and the second protrusion 52, and the surface shape (second surface shape) of the attachment surface PF of a heatsink base 14D includes the first recess 61 and the second recess 62. Note that the features of the present modification may also be applied to the modification described above of the first embodiment and other embodiments described later.

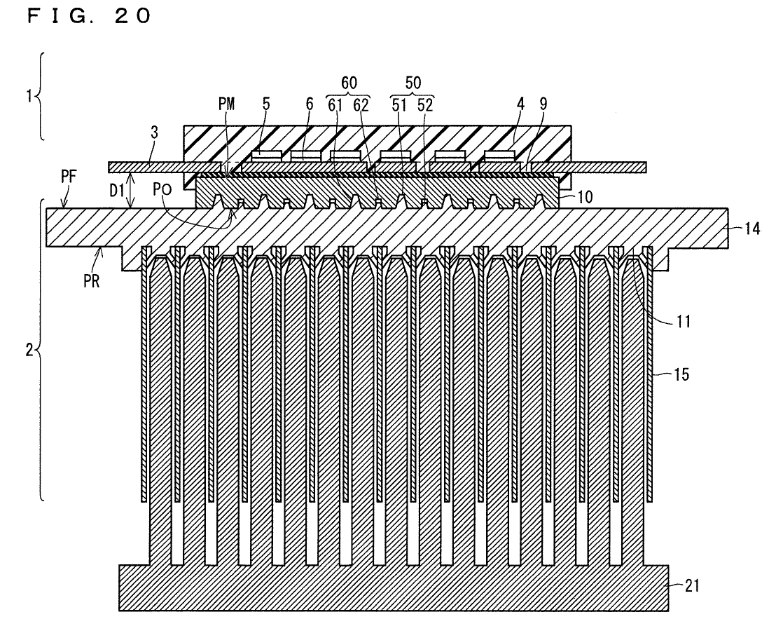

The heatsink swaging and the fin swaging described above may be performed simultaneously. FIGS. 18 to 20 are cross sectional views schematically showing a state immediately before the swaging process, during the swaging process, and immediately after the swaging process, respectively, in the method for manufacturing the power semiconductor device 101 (FIG. 1). With reference to FIGS. 18 and 19, the heat dissipation fin 15 is inserted into a fin insertion groove 20 of the heatsink base 14. Then, a jig 21 is inserted into the swage portion 11 of the heatsink base 14. Then, a load is applied between the power module unit 1 and the jig 21 in the thickness direction in a state where the power module unit 1 is in contact with the attachment surface PF of the heatsink base 14. This simultaneously performs heatsink swaging and fin swaging. This method is suitable when the planar layout shown in FIG. 3 is used.

Note that the heatsink swaging may be performed by applying a load such that the back surface PO of the power module unit 1 is pressed against the attachment surface PF of the heatsink unit 2M (FIG. 11) or the heatsink unit 2N (FIG. 12) supported by a jig similar to the jig 23. Unlike the jig 23, the jig in that case preferably has a tip end having a wide flat surface without having a tapered shape.

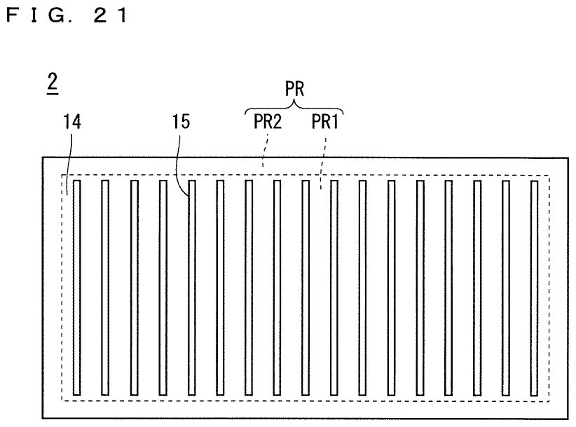

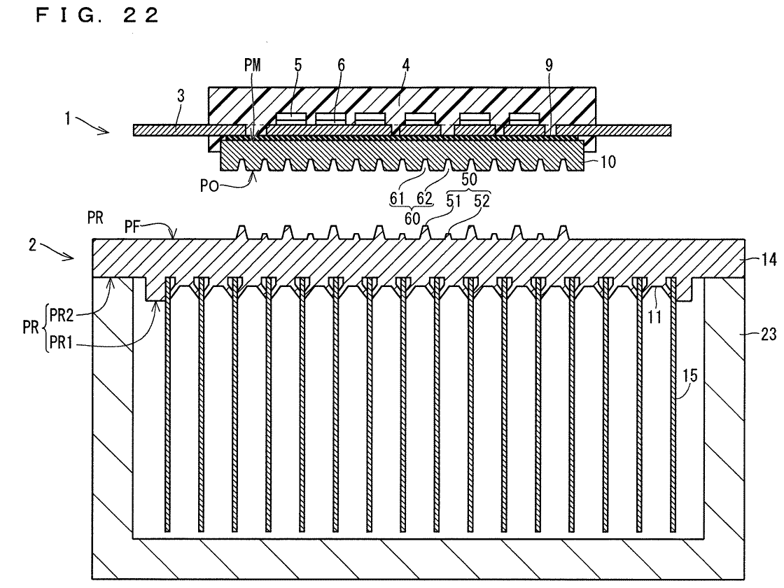

Alternatively, the heatsink swaging may be performed after the fin swaging. FIG. 21 is a plan view for explaining the method, and FIG. 22 is a cross sectional view for explaining the method. In the case of this method, the jig 23 supporting an outer region PR2 around an inner region PR1 attached with the heat dissipation fin 15 is used in the heat dissipation surface PR of the heatsink unit 2 formed by the fin swaging. The heatsink swaging is performed by applying a load so that the back surface PO of the power module unit 1 is pressed against the attachment surface PF of the heatsink unit 2 supported by the jig 23. This method is suitable when the planar layout shown in FIG. 3 is not used (e.g., when the planar layout shown in FIG. 4 or 5 is used).

### Second Embodiment

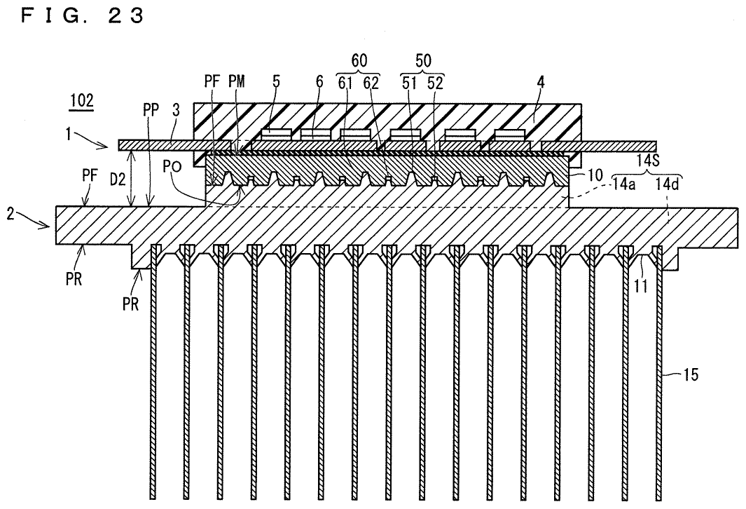

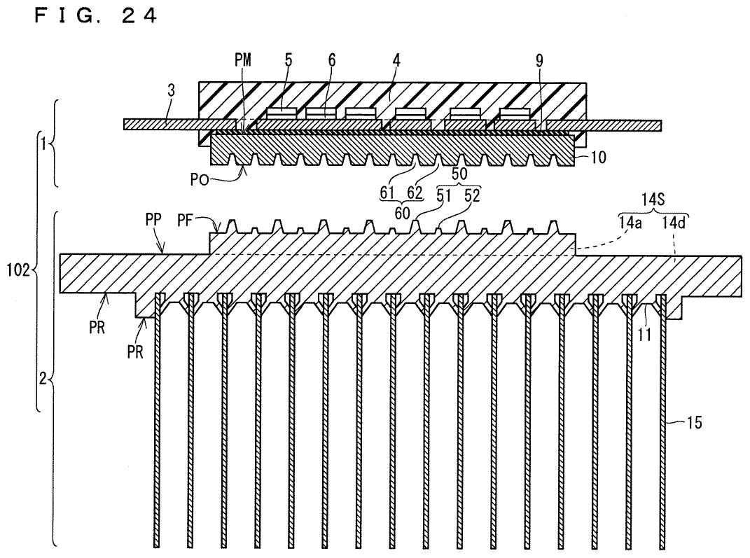

FIG. 23 is a cross sectional view schematically showing the configuration of a power semiconductor device 102 in the second embodiment. The power semiconductor device 102 includes a heatsink base 14S in place of the heatsink base 14 of the power semiconductor device 101 (FIG. 1). Other configurations are substantially the same as those of the above-described first embodiment (FIGS. 1 and 2). FIG. 24 is a cross sectional view schematically showing a state before swaging joint of the module base 10 and the heatsink base 14S of the power semiconductor device 102 shown in FIG. 23.

The heatsink base 14S includes an outer surface PP opposite to the heat dissipation surface PR (lower surfaces of the heatsink base 14S in FIGS. 23 and 24) disposed outside the attachment surface PF in an in-plane direction (lateral directions in FIGS. 23 and 24) perpendicular to the thickness direction. The outer surface PP is disposed to be shifted (in other words, shifted in downward directions in FIGS. 23 and 24) toward the heat dissipation surface PR relative to the attachment surface PF in the thickness direction. As described above, in the second embodiment, in addition to the attachment surface PF, the outer surface PP is provided as a surface opposite to the heat dissipation surface PR. Therefore, in the second embodiment, the outer area of the heat dissipation surface PR is larger than the outer area of the attachment surface PF.

The heatsink base 14S can be deemed to include a module attachment portion 14a forming the attachment surface PF and a heat diffusing portion 14d forming the outer surface PP and the heat dissipation surface PR. The heat diffusing portion 14d and the module base 10 are separated from each other by the module attachment portion 14a. The heat diffusing portion 14d extends to the outside of the module attachment portion 14a in the in-plane direction. Note that a boundary (broken lines in FIGS. 23 and 24) between the module attachment portion 14a and the heat diffusing portion 14d may be virtual.

The part projecting from the resin sealing portion 4 of the lead frame 3 does not face the attachment surface PF but faces the outer surface PP at a distance D2 in the thickness direction. The distance D2 corresponds to an insulation distance (distance typically separated by air) between the lead frame 3 and the heatsink base 14S. On the other hand, an insulation distance between the lead frame 3 and the heatsink base 14 (FIG. 1: the first embodiment) corresponds to a distance D1 (FIG. 1), which is substantially the same as the thickness of the module base 10. Therefore, in order to increase the insulation distance in the first embodiment described above, it is necessary to increase the thickness of the module base 10. An excessive thickness of the module base 10 leads to a reduction in productivity of the power semiconductor device. Specifically, first, since the heat capacity of the module base 10 increases, the time required to raise the temperature to the process temperature in a formation process of the resin sealing portion 4 in the manufacture of the power semiconductor device 101, that is, a molding process increases, and thus productivity is reduced. Second, since the mold for the molding process increases, the apparatus for performing the molding process also increases, thereby reducing productivity. Third, since the heat capacity increases as the mold for the molding process increases, the time required to raise the mold to the process temperature increases, thereby reducing productivity.

According to the second embodiment, the outer surface PP is disposed to be shifted toward the heat dissipation surface PR relative to the attachment surface PF in the thickness direction. Due to this, the distance between the lead frame 3 projecting from the resin sealing portion 4 and the outer surface PP of the heatsink base 14S facing the lead frame 3 in the thickness direction, that is, the insulation distance can be increased without depending only on the thickness of the module base 10.

### Third Embodiment

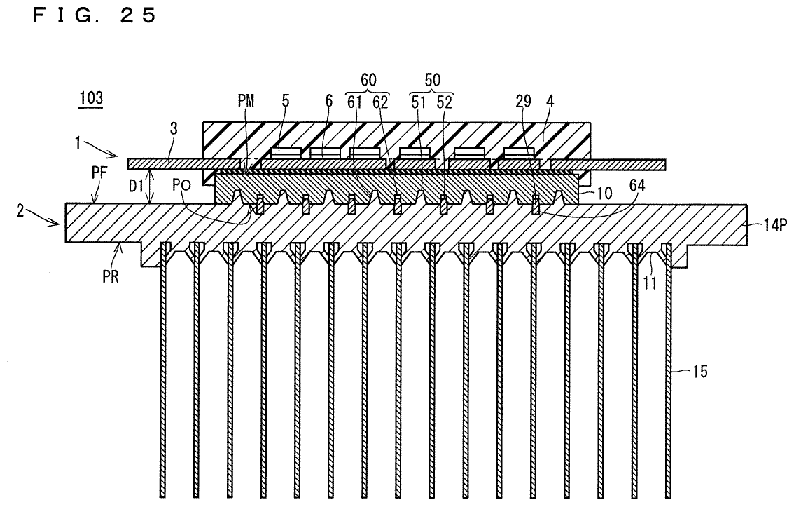

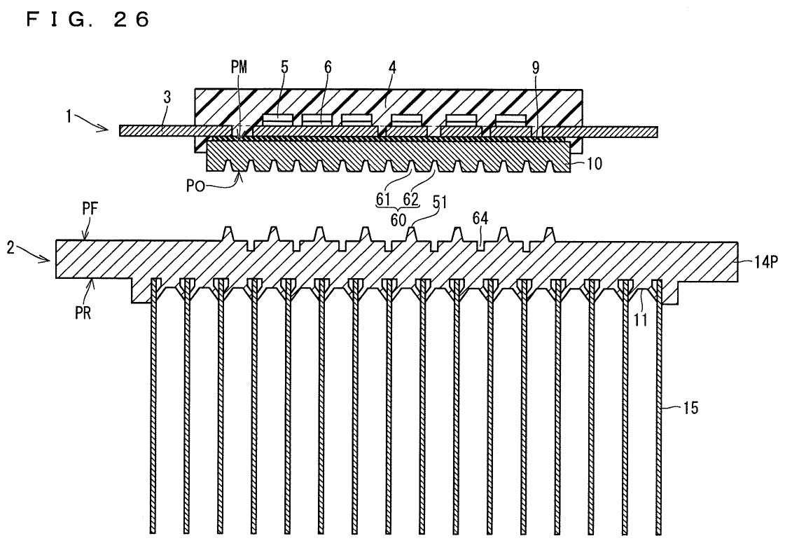

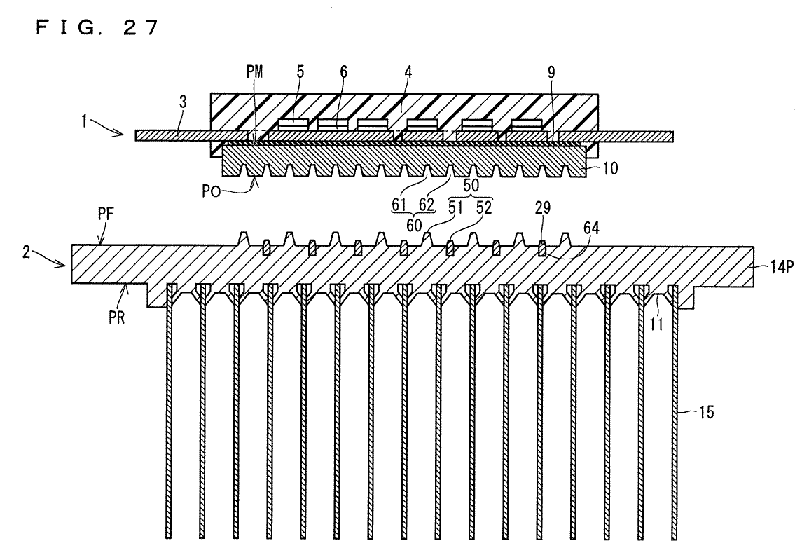

FIG. 25 is a cross sectional view schematically showing the configuration of a power semiconductor device 103 in the third embodiment. FIGS. 26 and 27 are cross sectional views schematically showing the process in the method for manufacturing the power semiconductor device 103.

A heatsink base 14P includes a third recess 64 and a pin member 29 including an insertion portion inserted into the third recess 64 and a projection portion projecting from the third recess 64. This projecting portion constitutes the second protrusion 52. Note that the boundary between the third recess 64 and the pin member 29 can be actually observed. The third recess 64 of the heatsink base 14P is made of a first metal material, and the pin member 29 of the heatsink base 14P is made of a second metal material. Portions of the heatsink base 14P other than the pin member 29 may be made of the first metal material. The second metal material may be the same as or different from the first metal material. In the latter case, the second metal material is preferably a material harder than the first metal material, thereby suppressing plastic deformation of the second protrusion 52 in the heatsink swaging. Therefore, an increase in surface pressure between the second recess 62 and the second protrusion 52 due to a reduction in the second recess 62 can be made rapider. Therefore, the effects described in the first embodiment can be further enhanced. Note that the configuration other than the above is substantially the same as the configuration of the first embodiment (FIG. 1) described above.

According to the present embodiment, after the attachment surface PF including the first protrusion 51 is formed (see FIG. 26), the second protrusion 52 is provided on the attachment surface PF by insertion of the pin member 29 (see FIG. 27). This eliminates the need for simultaneously forming the second protrusion 52 when forming the first protrusion 51. Therefore, it is possible to reduce the difficulty in manufacturing the heatsink base 14P in view of the aspect ratio of the attachment surface PF and the like.

Note that as a modification, as described above with reference to FIG. 17, the second protrusion 52 and the third recess 64 into which the second protrusion 52 is inserted may be included in the surface shape (first surface shape) of the back surface PO of the module base in place of the surface shape (second surface shape) of the attachment surface PF of the heatsink base. In that case, the third recess 64 of the module base is made of the first metal material, and the pin member 29 of the module base is made of the second metal material. Portions of the module base other than the pin member 29 may be made of the first metal material. The second metal material may be the same as or different from the first metal material. In the latter case, the second metal material is preferably a harder material than the first metal material.

### Fourth Embodiment

In the present embodiment, the power semiconductor device according to at least any of the first to third embodiments described above is applied to a power conversion apparatus. Although the application of the power semiconductor device according to the first to third embodiments is not limited to a specific power conversion apparatus, a case where the power semiconductor device according to at least any of the first to third embodiments is applied to a three-phase inverter will be described below as the first to third embodiments.

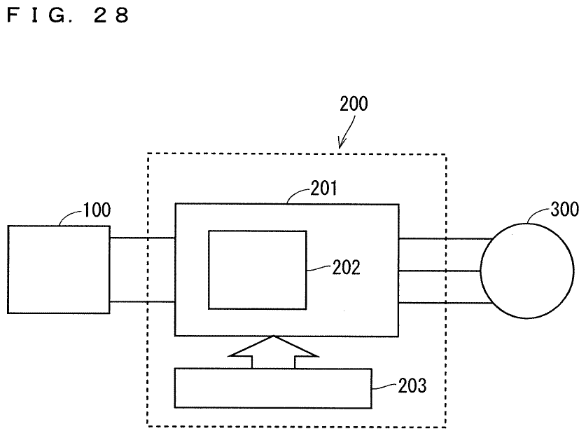

FIG. 28 is a block diagram showing the configuration of a power conversion system applied with the power conversion apparatus according to the present embodiment.

The power conversion system shown in FIG. 28 includes a power source 100, a power conversion apparatus 200, and a load 300. The power source 100 is a direct-current power source, and supplies the power conversion apparatus 200 with direct-current power. The power source 100 can be configured with various components, and can be configured with, for example, a direct-current system, a solar battery, and a storage battery, or may be configured with a rectifier circuit or an AC/DC converter connected to an alternating-current system. The power source 100 may be configured with a DC/DC converter that converts direct-current power output from a direct-current system into predetermined power.

The power conversion apparatus 200 is a three-phase inverter connected between the power source 100 and the load 300, converts direct-current power supplied from the power source 100 into alternating-current power, and supplies the load 300 with the alternating-current power. As shown in FIG. 28, the power conversion apparatus 200 includes a main conversion circuit 201 that converts direct-current power into alternating-current power and outputs the alternating-current power, and a control circuit 203 that outputs, to the main conversion circuit 201, a control signal for controlling the main conversion circuit 201.

The load 300 is a three-phase electric motor driven by the alternating-current power supplied from the power conversion apparatus 200. The load 300 is not limited to a specific application but is an electric motor mounted on various types of electric equipment, and is used as an electric motor for, for example, a hybrid vehicle, an electric vehicle, a railway vehicle, an elevator, or an air conditioner.

Hereinafter, details of the power conversion apparatus 200 will be described. The main conversion circuit 201 includes a switching element and a freewheeling diode (not shown), converts direct-current power supplied from the power source 100 into alternating-current power by switching of the switching element, and supplies the alternating-current power to the load 300. Although there are various specific circuit configurations of the main conversion circuit 201, the main conversion circuit 201 according to the present embodiment is a two-level three-phase full-bridge circuit, and can include six switching elements and six freewheeling diodes connected in an antiparallel manner to the respective switching elements. Each of the switching elements and each of the freewheeling diodes of the main conversion circuit 201 are configured by a semiconductor module 202 corresponding to the power semiconductor device according to at least any of the first to third embodiments described above. The six switching elements are connected in series for every two switching elements to constitute upper and lower arms, and each of the upper and lower arms constitutes each phase (U-phase, V-phase, and W-phase) of the full-bridge circuit. Then, an output terminal of each of the upper and lower arms, that is, three output terminals of the main conversion circuit 201 are connected to the load 300.

The main conversion circuit 201 includes a drive circuit (not shown) that drives each of the switching elements, but the drive circuit may be built in the semiconductor module 202, or may be configured to include a drive circuit separately from the semiconductor module 202. The drive circuit generates a drive signal for driving the switching element of the main conversion circuit 201, and supplies the drive signal to a control electrode of the switching element of the main conversion circuit 201.

Specifically, in accordance with a control signal from the control circuit 203 described later, a drive signal for bringing the switching element into an on state and a drive signal for bringing the switching element into an off state are output to the control electrode of the respective switching elements. When the switching element is maintained in the on state, the drive signal is a voltage signal (on signal) equal to or greater than a threshold voltage of the switching element, and when the switching element is maintained in the off state, the drive signal becomes a voltage signal (off signal) equal to or less than the threshold voltage of the switching element.

The control circuit 203 controls the switching elements of the main conversion circuit 201 so that the load 300 is supplied with desired power. Specifically, a time (on time) at which each of the switching elements of the main conversion circuit 201 should be brought into the on state is calculated based on the power to be supplied to the load 300. For example, it is possible to control the main conversion circuit 201 by PWM control of modulating the on time of the switching element depending on to the voltage to be output. Then, a control command (control signal) is output to the drive circuit of the main conversion circuit 201 so that an on signal is output to the switching element to be brought into the on state at each time point, and an off signal is output to the switching element to be brought into the off state at each time point. The drive circuit outputs, as a drive signal, an on signal or an off signal to the control electrode of each of the switching elements in accordance with this control signal.

The power conversion apparatus according to the present embodiment is applied with the power semiconductor device according to at least any of the first to third embodiments as that including at least any of the switching element and the freewheeling diode of the main conversion circuit 201. This can improve productivity or reliability of the power conversion apparatus.

In the present embodiment, an example in which the two-level three-phase inverter is applied with the power semiconductor device according to at least any of the first to third embodiments has been described, but the application of the power semiconductor device according to at least any of the first to third embodiments is not limited to this, and the power semiconductor device can be applied to various power conversion apparatuses. In the present embodiment, the two-level power conversion apparatus is assumed, but a three-level or multi-level power conversion apparatus may be assumed, and, in a case where a single-phase load is supplied with power, a single-phase inverter may be applied with the power semiconductor device according to at least any of the first to third embodiments. In a case of supplying power to a direct-current load or the like, it is also possible to apply a DC/DC converter or an AC/DC converter with the power semiconductor device according to at least any of the first to third embodiments.

The power conversion apparatus applied with the power semiconductor device according to at least any of the first to third embodiments is not limited to the case where the above-described load is an electric motor, and the power conversion apparatus can be used, for example, as a power source apparatus for an electric discharge machine, a laser beam machine, an induction heating cooker, or a noncontact power supply system, and can also be used as a power conditioner for a photovoltaic system, a power storage system, or the like.

The embodiments can be freely combined, and the embodiments can be appropriately modified or omitted.

### Appendix

Hereinafter, various aspects of the present disclosure will be collectively described as appendices.

### Appendix 1

A power semiconductor device (101 to 103, 101V) comprising:
a module base (10, 10A to 10D) having a mounting surface (PM) and a back surface (PO) opposite to the mounting surface (PM) in a thickness direction;
a semiconductor element (5) mounted on the mounting surface (PM) of the module base (10, 10A to 10D);
a resin sealing portion (4) sealing the semiconductor element (5) on the mounting surface (PM) of the module base (10, 10A to 10D); and
a heatsink base (14, 14A to 14D, 14M, 14N, 14P, 14S) having an attachment surface (PF) attached to the back surface (PO) of the module base (10, 10A to 10D) and a heat dissipation surface (PR) opposite to the attachment surface (PF) in the thickness direction,
wherein a first surface shape of the back surface (PO) of the module base (10, 10A to 10D) and a second surface shape of the attachment surface (PF) of the heatsink base (14, 14A to 14D, 14M, 14N, 14P, 14S) are fitted to each other, and thus the back surface (PO) of the module base (10, 10A to 10D) and the attachment surface (PF) of the heatsink base (14, 14A to 14D, 14M, 14N, 14P, 14S) are fixed to each other,
one of the first surface shape and the second surface shape includes a first protrusion (51) and a second protrusion (52), and an other includes a first recess (61) fitted with the first protrusion (51) and a second recess (62) fitted with the second protrusion (52), and
the first protrusion (51) has a tip end in contact with the first recess (61), and the second protrusion (52) has a tip end (TE) away from the second recess (62).

### Appendix 2

The power semiconductor device (101 to 103, 101V) according to appendix 1, wherein in the cross sectional view parallel to the thickness direction, a height (H52) of the second protrusion is 0.5 mm or more, and a width (W52) of the second protrusion is 65% or more and less than 100% of a width (W62) of the second recess.

### Appendix 3

The power semiconductor device (101 to 103, 101V) according to appendix 1 or 2, wherein in a cross sectional view parallel to the thickness direction, no gap is formed or a gap smaller than a gap (GP) between the second protrusion (52) and the second recess (62) is formed between the first protrusion (51) and the first recess (61).

### Appendix 4

The power semiconductor device (101 to 103, 101V) according to any one of appendices 1 to 3, wherein in a cross sectional view parallel to the thickness direction, no gap is formed or a gap having an area of 50% or less of an area of the first recess (61) is formed between the first protrusion (51) and the first recess (61).

### Appendix 5

The power semiconductor device (101 to 103, 101V) according to any one of appendices 1 to 4, wherein a surface pressure is applied at least locally between the first protrusion (51) and the first recess (61).

### Appendix 6

The power semiconductor device (101 to 103, 101V) according to any one of appendices 1 to 5, wherein no surface pressure is applied or a maximum surface pressure lower than a maximum surface pressure between the first protrusion (51) and the first recess (61) is applied between the second protrusion (52) and the second recess (62).

### Appendix 7

The power semiconductor device (101 to 103, 101V) according to any one of appendices 1 to 6, wherein a surface pressure is applied at least locally between the second protrusion (52) and the second recess (62).

### Appendix 8

The power semiconductor device (102) according to any one of appendices 1 to 7, wherein
the heatsink base (14S) includes an outer surface (PP) opposite to the heat dissipation surface (PR), the outer surface (PP) being disposed outside the attachment surface (PF) in an in-plane direction perpendicular to the thickness direction, and
the outer surface (PP) is disposed to be shifted toward the heat dissipation surface (PR) relative to the attachment surface (PF) in the thickness direction.

### Appendix 9

The power semiconductor device (101 to 103, 101V) according to any one of appendices 1 to 8, wherein a planar layout perpendicular to the thickness direction of a recess group (60) including the first recess (61) and the second recess (62) includes a plurality of patterns each extending along a first direction and arranged at intervals in a second direction perpendicular to the first direction.

### Appendix 10

The power semiconductor device (101 to 103, 101V) according to any one of appendices 1 to 8, wherein a planar layout perpendicular to the thickness direction of a recess group (60) including the first recess (61) and the second recess (62) includes a plurality of patterns (P1) each extending along a first direction and arranged at intervals in a second direction perpendicular to the first direction, and at least one pattern (P2) extending along a third direction different from the first direction.

### Appendix 11

The power semiconductor device (103) according to any one of appendices 1 to 10, wherein the module base or the heatsink base includes a third recess (64), and a member (29) including an insertion portion inserted into the third recess (64) and a projection portion projecting from the third recess (64), and the projection portion constitutes the second protrusion (52).

### Appendix 12

A power conversion apparatus (200) comprising:
a main conversion circuit (201) that includes the power semiconductor device (101 to 103, 101V) according to any one of appendices 1 to 11 and converts and outputs power that is input; and
a control circuit (203) that outputs a control signal for controlling the main conversion circuit (201) to the main conversion circuit (201).

### EXPLANATION OF REFERENCE SIGNS

1: power module unit
2, 2M, 2N: heatsink unit
3: lead frame
4: resin sealing portion
5: semiconductor element
10, 10A to 10D: module base
14, 14A to 14D, 14M, 14N, 14P, 14S: heatsink base
15, 15M, 15N: heat dissipation fin
29: pin member
51: first protrusion
52: second protrusion
60: recess group
61: first recess
62: second recess
64: third recess
101 to 103: power semiconductor device
200: power conversion apparatus
201: main conversion circuit
203: control circuit
PF: attachment surface
PM: mounting surface
PO: back surface
PP: outer surface
PR: heat dissipation surface

1. A power semiconductor device comprising:
a module base having a mounting surface and a back surface opposite to the mounting surface in a thickness direction;
a semiconductor element mounted on the mounting surface of the module base;
a resin sealing portion sealing the semiconductor element on the mounting surface of the module base; and
a heatsink base having an attachment surface attached to the back surface of the module base and a heat dissipation surface opposite to the attachment surface in the thickness direction,
wherein a first surface shape of the back surface of the module base and a second surface shape of the attachment surface of the heatsink base are fitted to each other, and thus the back surface of the module base and the attachment surface of the heatsink base are fixed to each other,
one of the first surface shape and the second surface shape includes a first protrusion and a second protrusion, and an other includes a first recess fitted with the first protrusion and a second recess fitted with the second protrusion, and
the first protrusion has a tip end in contact with the first recess, and the second protrusion has a tip end away from the second recess, and the second protrusion is lower than the first protrusion.

2. The power semiconductor device according to claim 1, wherein in a cross sectional view parallel to the thickness direction, a height of the second protrusion is 0.5 mm or more, and a width of the second protrusion is 65% or more and less than 100% of a width of the second recess.

3. The power semiconductor device according to claim 1, wherein in a cross sectional view parallel to the thickness direction, no gap is formed or a gap smaller than a gap between the second protrusion and the second recess is formed between the first protrusion and the first recess.

4. The power semiconductor device according to claim 1, wherein in a cross sectional view parallel to the thickness direction, no gap is formed or a gap having an area of 50% or less of an area of the first recess is formed between the first protrusion and the first recess.

5. The power semiconductor device according to claim 1, wherein a surface pressure is applied at least locally between the first protrusion and the first recess.

6. The power semiconductor device according to claim 1, wherein no surface pressure is applied or a maximum surface pressure lower than a maximum surface pressure between the first protrusion and the first recess is applied between the second protrusion and the second recess.

7. The power semiconductor device according to claim 1, wherein a surface pressure is applied at least locally between the second protrusion and the second recess.

8. The power semiconductor device according to claim 1, wherein
the heatsink base includes an outer surface opposite to the heat dissipation surface, the outer surface being disposed outside the attachment surface in an in-plane direction perpendicular to the thickness direction, and
the outer surface is disposed to be shifted toward the heat dissipation surface relative to the attachment surface in the thickness direction.

9. The power semiconductor device according to claim 1, wherein a planar layout perpendicular to the thickness direction of a recess group including the first recess and the second recess includes a plurality of patterns each extending along a first direction and arranged at intervals in a second direction perpendicular to the first direction.

10. The power semiconductor device according to claim 1, wherein a planar layout perpendicular to the thickness direction of a recess group including the first recess and the second recess includes a plurality of patterns each extending along a first direction and arranged at intervals in a second direction perpendicular to the first direction, and at least one pattern extending along a third direction different from the first direction.

11. The power semiconductor device according to claim 1, wherein the module base or the heatsink base includes a third recess, and a member including an insertion portion inserted into the third recess and a projection portion projecting from the third recess, and the projection portion constitutes the second protrusion.

12. A power conversion apparatus comprising:
a main conversion circuit that includes the power semiconductor device according to claim 1 and converts and outputs power that is input; and
a control circuit that outputs a control signal for controlling the main conversion circuit to the main conversion circuit.

13. The power semiconductor device according to claim 1, wherein in a cross sectional view parallel to the thickness direction, the first protrusion is one of a plurality of first protrusions and the second protrusion is one of a plurality of second protrusions, the first protrusions and the second protrusions being alternately arranged, all the second protrusions being disposed between a pair of protrusions included in the plurality of the first protrusions.
